(19) United States
(12) Patent Application Publication
(10) Pub. No.: US 2013/0341745 A1
(43) Pub. Date: Dec. 26, 2013

(54) Magnetic Field Measurement Apparatus

(71) Applicants: Seiichi Suzuki, Tokyo (JP); Taro Osabe, Tokyo (JP); Ryuzo Kawabata, Tokyo (JP)

(72) Inventors: Seiichi Suzuki, Tokyo (JP); Taro Osabe, Tokyo (JP); Ryuzo Kawabata, Tokyo (JP)

(73) Assignee: Hitachi, Ltd., Chiyoda-ku, Tokyo (JP)

(21) Appl. No.: 13/980,579

(22) PCT Filed: Mar. 14, 2011
(86) PCT No.: PCT/JP2011/055880

§ 371 Date: Jul. 19, 2013

(51) Int. Cl. H01L 43/02

(52) U.S. Cl. CPC H01L 43/02
USPC 257/427

(57) ABSTRACT

A light pumping magnetic measurement apparatus configured to suppress an influence on a magnetic field from a heater and facilitate reduction in size and integration of a gas cell when heating the gas cell in order to improve a sensitivity of detection of the magnetic field is provided. This measurement apparatus includes a first glass substrate, a substrate 102 having a thermal conductivity higher than glass, and a second glass substrate laminated in this order. At least one portion of a through hole formed on the substrate 102 having a thermal conductivity higher than the glass and penetrating therethrough when viewed in cross section constitutes a void 111 hermetically sealed by the first glass substrate and the second glass substrate, the void is filled with alkali metal gas generated by an alkali metal solid substance or liquid 112, and a flow channel (through hole) 113 connected to inlet-outlet ports 114 provided on the laminated substrate is formed in the vicinity of the void 111 of a substrate 103, so that the temperature of the alkali metal gas may be adjusted by causing the fluid to flow to the flow channel (through hole).

### TECHNICAL FIELD

The present invention relates to a structure of a magnetic field measurement apparatus and, more specifically, to a structure of a gas cell which realizes heating of a sensor portion in a light pumping magnetometer.

### BACKGROUND ART

Ina light pumping magnetometer, increase in alkali metal atomicity in an alkali metal gas cell as a sensor portion is absolutely imperative. In order to increase the alkali atomicity, it is effective to heat the gas cell to increase saturated vapor pressure of alkali metal gas. In order to heat the gas cell, there is a method of utilizing a heater or warm air.

PTL 1 describes installing a conducting glass or a transparent film heater in a portion of the glass-made gas cell where irradiated light passes, distributing power to the conducting glass or the transparent film heater, thereby heating the glass-made gas cell.

PTL 2 and PTL 3 describe installing an oven in which the glass-made gas cell is stored and a thermal insulating layer in the periphery of the oven, allowing heated nitrogen gas or air to flow into the container from the outside, and heating the glass-made gas cell.

NPL 1 describes installing a transparent ITO (Indium Tin Oxide) heater at a portion where irradiated light passes in the gas cell made of a silicon substrate and glass, distributing power to the transparent ITO heater, thereby heating the glass of the cell.

NPL 2 describes allowing warm air to flow into a coil-shaped plastic tube installed around a glass-made gas cell, thereby heating the glass-made gas cell.

### CITATION LIST

### Patent Literature

PTL 1: JP-A-2009-010547
PTL 2: JP-A-2009-236598
PTL 3: JP-A-2009-236599

### Non Patent Literatures

NPL 1: Peter D. D. Schwindt et. al “Chip-scale atomic magnetometer with improved sensitivity by use of the Mx technique”, Applied Physics Letters 90, 081102-1 to 081102-3 (2007)
NPL 2: G. Bison et al, “A laser-pumped magnetometer for the mapping of human cardiomagnetic fields”, Applied Physics B 76, p. 325 to 328 (2003)

### SUMMARY OF INVENTION

### Technical Problem

In PTL 1 and NPL 1, the conducting glass or the transparent film heater, or the transparent ITO heater is installed in a portion where irradiated light to the cell passes, and power is distributed to the conducting glass or the transparent film heater or the transparent ITO heater to heat the cell, and hence the cell advantageously reaches a desired temperature quickly. However, since a magnetostatic field to be applied to the cell may change due to an influence of a magnetic field from the heater, there is a problem of lowering in accuracy of magnetic field measurement.

In PTL 2 and PTL 3, heated nitrogen gas or air is allowed to flow into the oven in which the cell is stored from the outside, and the container is filled with the heated nitrogen gas or the air to heat the cell, so that influence of the magnetic field like the case of the heater is advantageously avoided. However, since the cell needs to be surrounded by the oven and the thermal insulating layer, there is a problem of increase in size of a sensor unit.

In NPL 2, warm air is allowed to flow into the coil-shaped plastic tube installed in the periphery of the cell to heat the cell, so that influence of the magnetic field like the case of the heater is advantageously avoided. However, since the tube is installed in the periphery of the cell, it may pose an impediment in reduction the size and integration of the cell.

### Solution to Problem

In the present invention, in a gas cell having a configuration in which a substrate having a thermal conductivity higher than glass is arranged between two glass substrates, an alkali metal gas cell formed with a through hole around a void formed in the substrate having a thermal conductivity higher than the glass and containing the alkali metal gas encapsulated therein is used. The gas cell is heated by allowing heated fluid to flow into the through hole. The term “fluid” includes gas and liquid except for solid substances.

According to an aspect of the present invention, fluid such as warm air or oil, for example, is heated and flowed into the through hole formed in the gas cell through tubing by using, for example, a heater and a pump arranged at positions which do not exert an influence upon a magnetic field for measurement, such as an outside of the magnetic shield in which the gas cell is stored, whereby the gas cell is heated.

According to another aspect of the present invention, a plurality of gas cells are arranged in series or in parallel, or in an array by combining series and parallel, and the heated fluid is allowed to flow into the through holes formed in the gas cells by using the heater and the pump arranged on the outside by using the tubing or a substrate with tubing, whereby a plurality of the gas cells are heated.

The representative present invention is a magnetic measurement apparatus including first and second glass substrates, a laminated substrate including a third substrate having a thermal conductivity higher than glass arranged between the first glass substrate and the second glass substrate, a void formed in the third substrate and filled with alkali metal gas, and a through hole formed in the third substrate so as to penetrate through two openings formed in the laminated substrate.

### Advantageous Effect of the Invention

According to the present invention, the influence of the power distribution exerted upon the magnetic field is smaller than heating by using the heater of the related art, and necessity of surrounding the gas cells with the oven and the thermal insulating layer is avoided in comparison with the heating achieved by causing warm air to hit against the gas cell of the related art, so that reduction in size of the apparatus is achieved. Also, in comparison with the heating in which the tube of the related art is installed in the peripheries of the gas cells and warm air is flowed in the interior thereof, since the flow channel is formed as a through hole in the gas cell, reduction in size and integration of the gas cells are easily achieved. Also, since the heated fluid flows through the substrate having a thermal conductivity higher than that of the glass, heating with a higher efficiency than the method of heating the glass is enabled.

### BRIEF DESCRIPTION OF THE DRAWINGS

FIG. 1 is a schematic drawing of a light pumping magnetometer according to a first embodiment of the present invention.

FIG. 2 is a schematic drawing of a magnetic field measurement apparatus according to the first embodiment.

FIG. 3 is a schematic drawing of the magnetic field measurement apparatus according to the first embodiment.

FIG. 4 is a schematic drawing of the magnetic field measurement apparatus according to the first embodiment.

FIG. 5 is a schematic drawing of the magnetic field measurement apparatus according to the first embodiment.

FIG. 6 (a), (b), (c) are flowcharts of manufacturing the magnetic field measurement apparatus according to the first embodiment.

FIG. 7 is a schematic drawing of the magnetic field measurement apparatus according to a second embodiment.

FIG. 8 is a schematic drawing of the magnetic field measurement apparatus according to the second embodiment.

FIG. 9 is a schematic drawing of the magnetic field measurement apparatus according to the second embodiment.

FIG. 10 is a schematic drawing of the magnetic field measurement apparatus according to the second embodiment.

FIG. 11 is a schematic drawing of the magnetic field measurement apparatus according to a third embodiment.

FIG. 12 is a schematic drawing of the magnetic field measurement apparatus according to the third embodiment.

FIG. 13 is a schematic drawing of the magnetic field measurement apparatus according to the third embodiment.

FIG. 14 is a schematic drawing of the magnetic field measurement apparatus according to a fourth embodiment.

FIG. 15 is a schematic drawing of the magnetic field measurement apparatus according to the fourth embodiment.

FIG. 16 is a schematic drawing of the magnetic field measurement apparatus according to the fourth embodiment.

FIG. 17 is a schematic drawing of the magnetic field measurement apparatus according to the fourth embodiment.

FIG. 18 is a schematic drawing of the magnetic field measurement apparatus according to a fifth embodiment.

FIG. 19 is a schematic drawing of the magnetic field measurement apparatus according to the fifth embodiment.

FIG. 20 is a schematic drawing of the magnetic field measurement apparatus according to the fifth embodiment.

FIG. 21 (a), (b), (c), (d), (e) are flowcharts of manufacturing the magnetic field measurement apparatus according to the fifth embodiment.

FIG. 22 is a schematic drawing of the magnetic field measurement apparatus according to a sixth embodiment.

FIG. 23 is a schematic drawing of the magnetic field measurement apparatus according to the sixth embodiment.

FIG. 24 is a schematic drawing of the magnetic field measurement apparatus according to the sixth embodiment.

FIG. 25 is a schematic drawing of the magnetic field measurement apparatus according to a seventh embodiment.

FIG. 26 is a schematic drawing of the magnetic field measurement apparatus according to the seventh embodiment.

FIG. 27 is a schematic drawing of the magnetic field measurement apparatus according to the seventh embodiment.

FIG. 28 is a schematic drawing of an array type magnetic field measurement apparatus according to an eighth embodiment.

FIG. 29 is a schematic drawing of an array type magnetic field measurement apparatus according to a ninth embodiment.

FIG. 30 is a schematic drawing of an array type magnetic field measurement apparatus according to a tenth embodiment.

### DESCRIPTION OF EMBODIMENTS

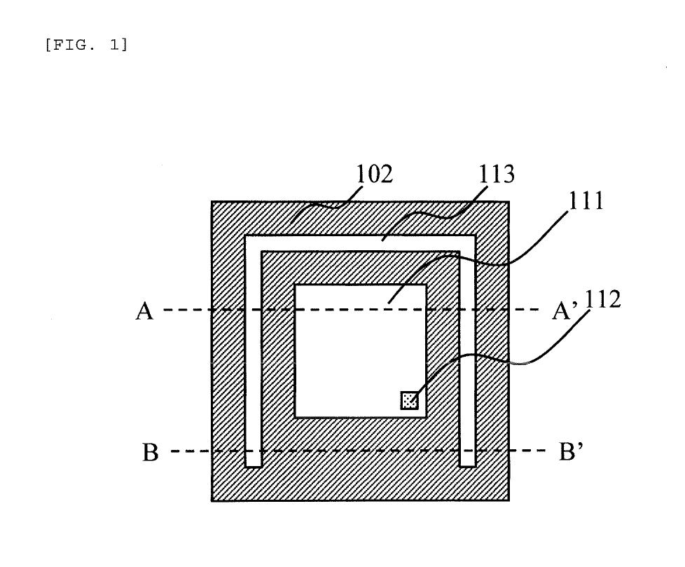

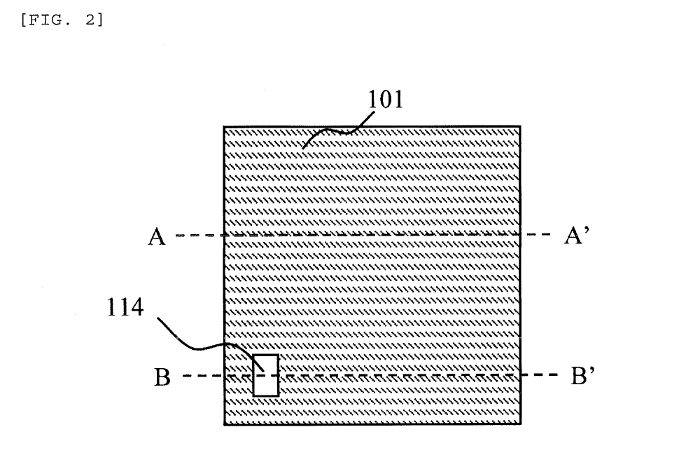

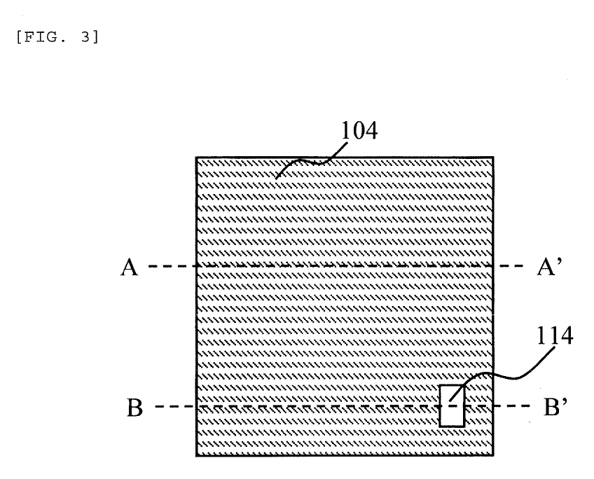

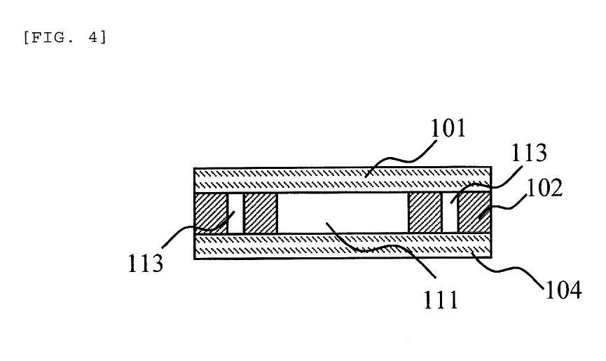

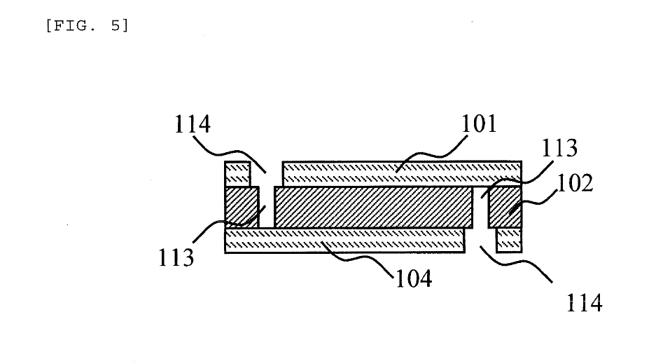

Referring now to the drawings, a basic structure of the present invention will be described. FIG. 1, FIG. 2, and FIG. 3 are schematic top views of a first glass substrate, a substrate having a thermal conductivity higher than glass, and a second glass substrate, respectively, of a gas cell according to the present invention, the gas cell having a flow channel (hereinafter, referred to also as a through hole) for allowing heated fluid to flow therethrough installed in the periphery of the gas cell to be irradiated with a laser beam for heating and formed of a laminated substrate including the glass substrate, and the substrate having a thermal conductivity higher than glass and the glass substrate. FIG. 4 and FIG. 5 are schematic cross-sectional views taken along the lines A-A′ and B-B′ in FIG. 1, respectively.

The gas cell in FIG. 4 has a laminated configuration including a glass substrate 101 and a glass substrate 104, and a substrate 102 having a thermal conductivity higher than the glass arranged therebetween, and the gas cell has a configuration in which a void 111 containing alkali metal solid substance or liquid 112 (see FIG. 1) which generates alkali metal gas therein and a flow channel (through hole) 113 are arranged in the substrate 102, and inlet-outlet ports (two openings) 114 (see FIGS. 2 and 3) connected to the flow channel (through hole) 113 are provided in the glass substrate 101 and the glass substrate 104. In other words, the flow channel 113 is configured as a through hole penetrating between the two openings which serve as inlet-outlet ports. The void 111 and the flow channel (through hole) 113 are formed by removing part of the substrate 102. The void 111 is hermetically sealed by the glass substrate 101 and the glass substrate 104, and a laser beam passes through the glass substrate 101 and the glass substrate 104. By connecting hollow tubing such as a tube from the outside to the inlet-outlet port 114 and allowing heated fluid to flow into the flow channel (through hole) 113, the substrate 102 is heated. The term “fluid” includes gas and liquid except for solid substances and is flowed into the flow channel (through hole) 113 for adjusting the temperature of the alkali metal gas. By the flow of the heated fluid in the substrate having a thermal conductivity higher than glass, alkali metal gas contained in the void 111 is heated to increase the vapor pressure, so that the alkali metal atomicity may be increased. In FIG. 1, the void has a rectangular shape, and the flow channel (through hole) 113 is arranged so as to surround three sides of the rectangular shape. However, the effects and advantages of the present invention are obtained by being provided at least in the substrate 102. By the arrangement of the flow channel (through hole) so as to surround the three sides of the rectangular shape as illustrated in FIG. 1, the heat of the fluid may be transferred to alkali metal gas in the void 111 with higher efficiency.

### First Embodiment

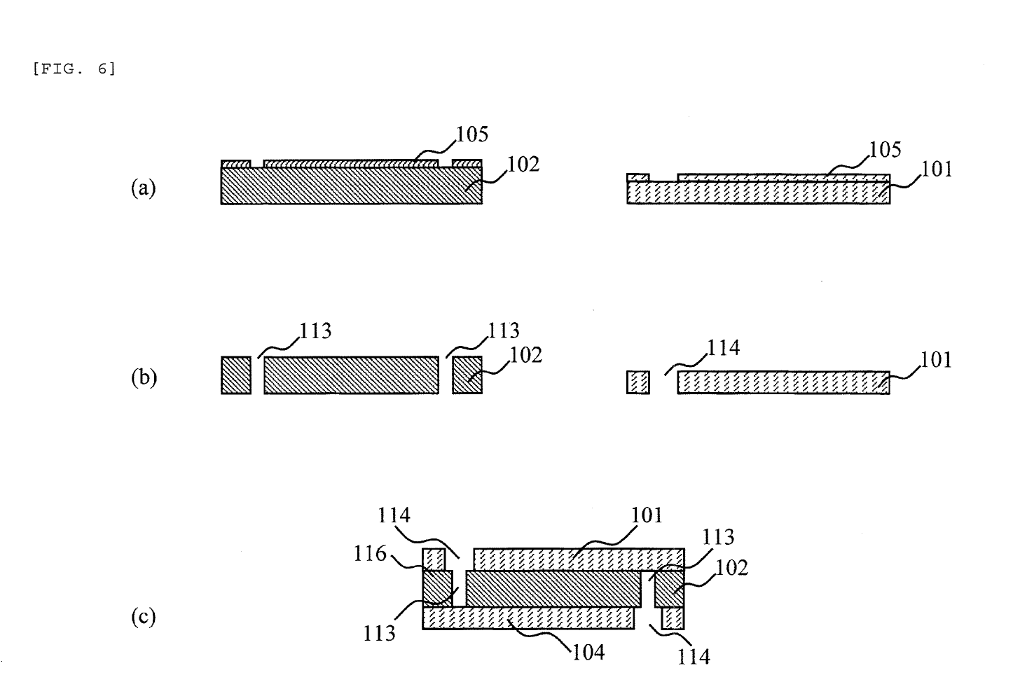

Referring to FIGS. 1 to 6, a first embodiment of the present invention will be described. FIG. 1, FIG. 2, and FIG. 3 are schematic top views illustrating the substrate 102, the glass substrate 101, and the glass substrate 104, respectively, of a gas cell according to the first embodiment. FIG. 4 and FIG. 5 are schematic cross-sectional views taken along the lines A-A′ and B-B′ in FIG. 1, respectively. FIGS. 6(a), (b), and (c) illustrate a method of manufacturing the gas cell according to the embodiment of the present invention by using a cross section taken along the line B-B′ in FIG. 1. In FIG. 6, the method of manufacturing the glass substrate 104 is omitted because it is the same as the method of manufacturing the glass substrate 101.

The gas cell according to this embodiment has a configuration including three layers of glass-substrate-glass, in which the glass substrate 101 is arranged on an upper surface of the substrate 102 and the glass substrate 104 is arranged on a lower surface thereof. For the substrate 102, a material having a thermal conductivity higher than the glass substrate 101 and the glass substrate 104, for example, a semiconductor substrate such as the silicone substrate is used. The glass substrate 101 and the glass substrate 104 are formed of a transparent material with respect to a laser beam to be irradiated, and are arranged so as to prevent alkali metal solid substance or the liquid 112 and alkali metal gas contained in the void 111 formed in the substrate 102 and fluid flowing in the flow channel 113 formed in the substrate 102 from leaking. The substrate 102 includes the void 111 in which alkali metal gas is encapsulated, the alkali metal solid substance or the liquid 112 arranged in the void ill, and the glass substrate 101 and the glass substrate 104 each include the inlet-outlet port 114 (see FIG. 2 and FIG. 3) connected to a flow channel and configured to allow the fluid to flow in and out.

The void 111 has a penetrated configuration when viewing the substrate 102 in cross section, and contains alkali metal gas generated from the alkali metal solid substance or the liquid 112 therein (see FIG. 4). The interior of the void 111 needs only to be tightly sealed in an area surrounded by the glass substrate 101 and the glass substrate 104, and may contain nitrogen gas, noble gas, or the like or a mixed atmosphere thereof instead of the alkali metal gas. Also, in FIG. 1, the shape of the void 111 is a rectangular shape. However, other polygonal shape or an area surrounded by a curve may be applicable. In this embodiment, a laser beam is irradiated from the upper glass substrate 101 toward the lower glass 104 substrate, and the laser beam passes through the void 111, whereby the magnetic field is measured.

The alkali metal solid substance or the liquid 112 is contained in the void 111 formed in the substrate 102, and generates alkali metal gas in the void 111 surrounded by the glass substrate 101 and the glass substrate 104. The alkali metal solid substance or the liquid 112 needs only to be a material which generates alkali metal gas, and a material which is capable of causing a compound or the like containing alkali metal, which is arranged therein, to generate alkali metal gas by using chemical reaction or the like may be used.

The flow channel 113 is preferably arranged so as to surround the periphery of the rectangular void 111 with straight lines over three sides thereof, although not necessarily essential. By surrounding the three sides of the rectangular, heat of the fluid may be transferred to the void 111 with high efficiency. Also, the flow channel 113 has a penetrating configuration when viewing the substrate 102 in cross section, and the substrate 102 is heated by heated fluid flowing therein through the inlet-outlet port 114, and the alkali metal gas in the void 111 is heated. When the alkali metal gas is heated, a saturated vapor pressure is increased, so that the alkali metal atomicity contributing to the magnetic field measurement is increased, and hence the detection sensitivity is advantageously increased. Here, by heating the substrate having a thermal conductivity higher than glass by the fluid, heating is achieved with higher efficiency than the method of heating the glass. Also, in comparison with the case where the heater is used, an electric current is not used for heating, and hence the influence is advantageously not exerted upon the measurement magnetic field.

The inlet-outlet ports 114 (two openings) are formed by arranging respectively through holes in the glass substrate 101 and the glass substrate 104 so as to connect the inlet-outlet port 114 for allowing the fluid to flow in and out to the flow channel 113. Heated fluid is infused from the outside into one of the inlet-outlet ports and the fluid is discharged from the other inlet-outlet port. The diameter of the through hole of the inlet-outlet ports 114 is larger than the diameter of the flow channel 113. This configuration has an advantage that positioning is easy when bonding or joining the glass substrate and the substrate 102, and that easiness of arrangement of the tubing above the flow channel when connecting the tubing which exchanges heated fluid with the outside and smooth inward and outward movement of the heated fluid are advantageously.

Subsequently, a procedure of manufacturing a gas cell for implementing the first embodiment will be described (FIG. 6). In this embodiment, a silicon substrate having a thermal conductivity higher than that of the glass is used as the substrate 102 as an example. In the embodiment in which the silicon substrate is used, for example, a substrate doped with an impurity such as phosphorus or boron may be used. In this configuration, the thermal conductivity is advantageously increased by impurity doping. Subsequently, a pattern of the void 111 and the flow channel 113 is formed on a mask material 105 formed on the substrate by lithography or the like, and the void 111 and the flow channel 113 are formed on the substrate 102 by etching or the like. As an example, a silicon oxide film is used as a mask material, and a through hole is formed in the substrate 102 according to the pattern by using dry etching using SiF₄ (silicon tetrafluoride) gas. Here, the cross sections of the void 111 and the flow channel 113 need not to be vertical, and may be oblique, or may have a level difference. Therefore, the void 111 and the flow channel 113 may be formed by another method, for example, by wet etching using KOH (potassium hydroxide) solution or the like or directly by shaping the substrate 102 with a laser or a drill or the like.

The glass substrate 101 and the glass substrate 104 are formed by using a material transparent with respect to the laser beam, for example, borosilicate glass or the like. In the same manner as the substrate 102, a pattern of the inlet-outlet ports 114 are formed in the mask material 105 by lithography or the like, and creates the through holes in the glass substrate 101 and the glass substrate 104 by etching or the like.

The glass substrate 101, the substrate 102, and the glass substrate 104 are bonded or joined and sealed in a state of containing the alkali metal solid substance or liquid 112 in the void 111 therein. For example, when the silicon substrate and the borosilicate glass are used, there is a method of joining by anode joining. In addition, a method of setting an atmosphere for bonding or joining the glass substrate 101 or the glass substrate 104 with inactive gas or noble gas of nitrogen or the like and encapsulating these gases in the void 111 at the same time is also applicable. Encapsulation of the inactive gas or the noble gas has an effect of suppressing spinning and scattering of the alkali metal gas. Between the substrate and the substrate, and between the glass substrate and the substrate are only required to be kept in hermeticity and an adhesive agent or the like may be used.

The inlet-outlet ports 114 are connected to the heater and the pump on the outside by tubing such as a silicone tube, and allow the heated fluid to be flowed therein. The shape of the inlet-outlet ports 114 may be a circular shape or the like so as to match the shape of the silicone tube or the like.

### Second Embodiment

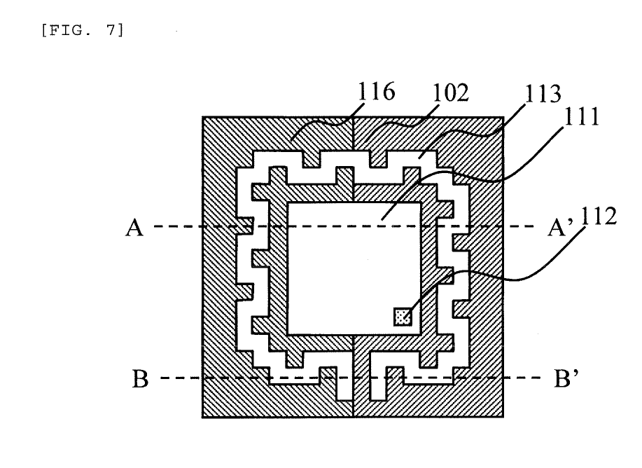

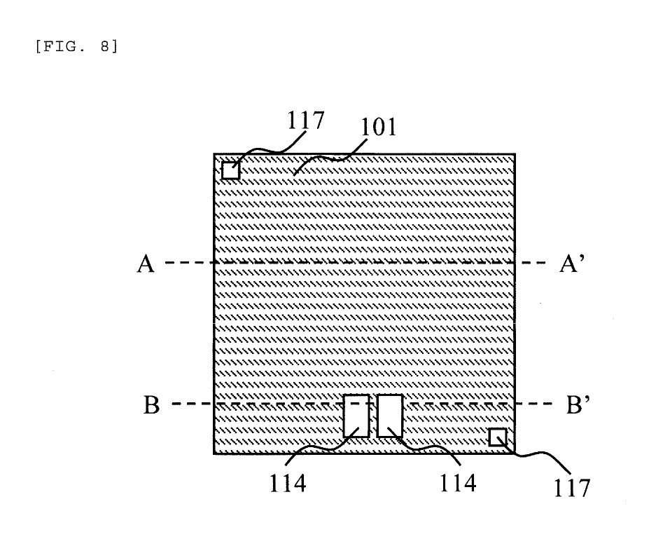

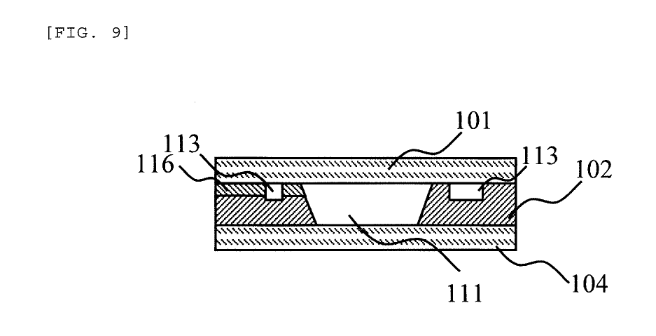

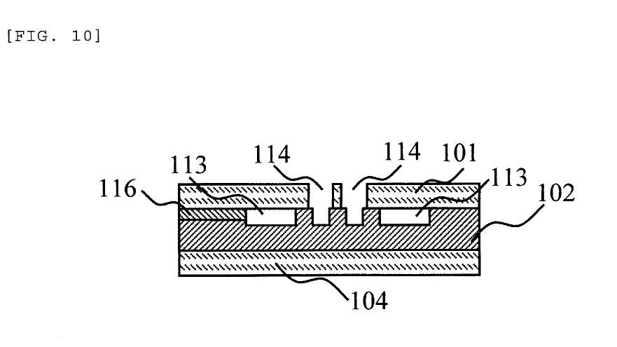

Referring to FIGS. 7 to 10, a second embodiment of the present invention will be described. FIG. 7 and FIG. 8 are schematic top views illustrating respectively the substrate 102 and the glass substrate 101 of a gas cell according to a second embodiment. FIG. 9 and FIG. 10 are schematic cross-sectional views taken along lines A-A′ and B-B′ in FIG. 7, respectively.

In the second embodiment, the gas cell has a configuration including three layers of the glass-substrate-glass in the same manner as the first embodiment. The void 111 is the same as that of the first embodiment. FIG. 9 illustrates a schematic cross-sectional view when a through hole is formed in the substrate 102 by anisotropic wet etching as an example, and illustrates a mode in which the cross-sectional shape is oblique. In a method of using the wet etching, since the through hole may be formed simply by soaking the substrate into etching solution, the manufacture is advantageously easy. The alkali metal solid substance or liquid 112 is the same as that of the first embodiment.

The flow channel 113 is arranged in a zigzag pattern in the horizontal direction with respect to the surface of the substrate 102. With the configuration having the flow channel so as to snake through in this manner, the entire length of the route of the flow channel may be elongated, and whereby the surface area on the side facing the void 111 may be secured to be larger than the route formed by connecting straight lines parallel to four sides of the rectangular substrate 102, whereby the heat of the heated fluid may be transferred with high efficiency. The flow channel 113 has a configuration not to penetrate through the substrate. In other words, the flow channel is in contact with the glass substrate 104 via part of the substrate. Accordingly, since the three sides of the flow channel 113 are configured of the substrate having a thermal conductivity higher than that of glass, the heat of the heated fluid is advantageously transferred to the substrate with high efficiency. The cross section of the flow channel 113 does not have to be the rectangular shape, and may be other polygonal shapes or circular shapes. There is a method using dry etching as described in the first embodiment for forming the flow channel 113. In FIG. 9 and FIG. 10, the flow channel 113 is arranged on the glass substrate 101 side of the substrate 102, but may be arranged on the glass substrate 104 side of the substrate 102 as a matter of course. In this case, the inlet-outlet ports 114 are arranged in the glass substrate 104 on the lower surface side.

The inlet-outlet ports 114 have a configuration in which through holes are arranged in the glass substrate 101, and the inlet-outlet ports 114 are connected to the flow channel 113. By arranging the two inlet-outlet ports 114 on the same surface, the tubing to be connected to the outside such as the silicone tube may be bundled together, so that wiring is advantageously easy. Here, in this embodiment, the arrangement of the flow channel 113 and the arrangement of the inlet-outlet ports 114 are changed in comparison with the first embodiment, and the respective effects are obtained independently.

In this embodiment, an n-type or P-type semiconductor substrate is used as the substrate 102, a p-type or n-type impurity area 116 is formed partly on the substrate 102 on the glass substrate 101 side to cause the same to work as a pn junction diode temperature sensor. Connection to the diode temperature sensor and an external temperature measurement system is achieved by forming the impurity area 116 on the glass substrate 101 and a temperature sensor terminal 117 at a position coming into contact with a part of the substrate 102 other than the above-described area and wiring among these members. In this method, since a magnetic material is not used, influence is advantageously not exerted upon the measurement magnetic field or the like. The fact that the substrate 102 reaches a desired temperature by using the temperature sensor is sensed, and subsequently, the magnetic field is measured. When measuring the magnetic field, it is preferable not to perform power distribution to the temperature sensor so as to avoid the influence of the magnetic field by the electric current flowing through the temperature sensor.

Subsequently, a procedure of manufacturing the gas cell for implementing the second embodiment will be described. As regards the shaping of the substrate 102, the void 111 is formed by creating a through hole when viewed from the cross section, and the flow channel 113 is formed by creating a partly penetrated groove when viewed from the cross section. Therefore, there is a method or the like of performing etching or the like at least twice and differentiating the amount of etching between the void 111 and the flow channel 113 or, alternatively, a method of drawing the patterns of the void 111 and the flow channel 113 on the upper surface of the substrate 102, drawing the pattern of the void 111 on the lower surface thereof, and etching or the like from the both surfaces of the substrate at the same time. Alternatively, the void 111 and the flow channel 113 may be formed directly by shaping the substrate 102 with a laser, a drill, or the like. In FIG. 9 and FIG. 10, a mode in which etching is performed twice, the void ill is formed by anisotropic wet etching, and the flow channel 113 is formed by isotropic dry etching is illustrated as an example. The diode temperature sensor forms the impurity area 116 on one side of the substrate 102 by lithography or the like, ion implantation, or heat diffusion.

As regards the shaping of the glass substrate 101 and the glass substrate 104, the inlet-outlet ports 114 are the same as those of the first embodiment, and the inlet-outlet ports 114 are arranged only in the glass substrate 101 in this embodiment. The temperature sensor terminal 117 configured to connect the diode temperature sensor and the outside is formed by creating a through hole in the glass substrate 101 so as to expose the impurity area 116 of the substrate 102 and an area other than the corresponding area of the substrate 102. Therefore, since the shaping of the glass substrate 104 is not necessary except for the shaping by cutting out into a size of the gas cell, an effect of reduction of the number of steps for shaping the glass substrate, and an effect of intensively arranging the tubing to be connected to the inlet-outlet ports of the gas cells and the wires to be connected to the temperature sensors on one side when a plurality of the gas cells are arranged are achieved. The bonding or the joining of the glass substrate 101 and the substrate 102 and the glass substrate 104 is the same as that of the first embodiment.

In the second embodiment, the flow channel 113 is arranged so as to snake through, the flow channel 113 is formed into a partly penetrated groove when viewing in cross section, the inlet-outlet ports 114 are arranged on the same surface on one of the glass substrates, and the temperature sensor is provided. However, even when one of these configurations is applied to the gas cell of the first embodiment, effects specific for the respective configurations may be obtained.

### Third Embodiment

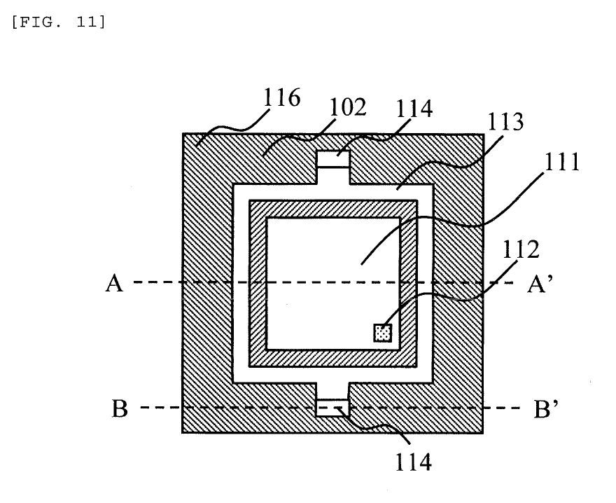

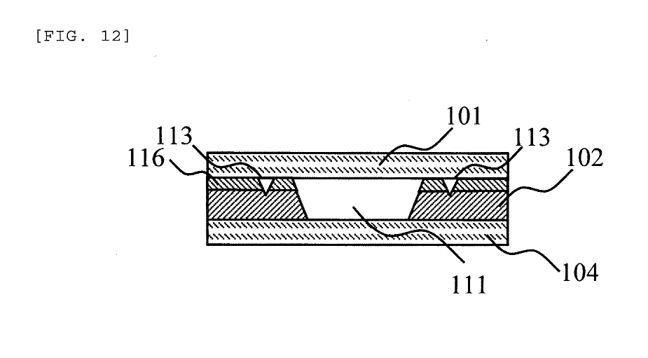

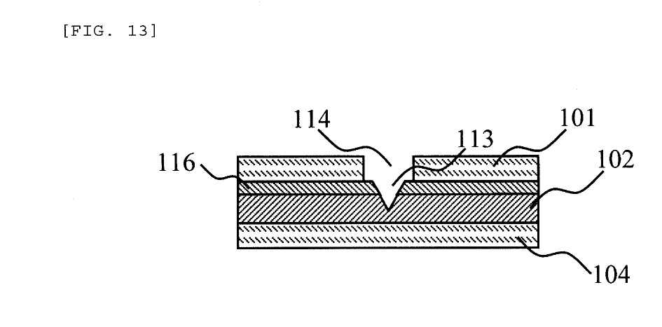

Referring to FIGS. 11 to 13, a third embodiment of the present invention will be described. FIG. 11 is a schematic top view of the substrate 102 in the gas cell according to the third embodiment. FIG. 12 and FIG. 13 are schematic cross-sectional views taken along lines A-A′ and B-B′ in FIG. 11, respectively. In the third embodiment, the gas cell has a configuration including the three layers of the glass-substrate-glass in the same manner as the first embodiment. The void 111 is the same as that of the first embodiment. The alkali metal solid substance or liquid 112 is the same as that of the first embodiment.

The flow channel 113 is arranged so as to surround the void 111 in parallel to the four sides of the substrate 102. The flow channel 113 is arranged so as to be bifurcated from one of the two inlet-outlet ports 114, is laid around the periphery of the void 111, and is coupled to a point in the vicinity of the other inlet-outlet ports 114. In FIG. 11, the flow channel 113 is arranged in a rectangular shape. However, other polygonal shape or a curved line may be used. Also, the cross-sectional shape of the flow channel 113 is the same as that of the second embodiment. Accordingly, the entire periphery of the void 111 is surrounded by the flow channel 113, so that alkali metal gas in the void 111 may be heated with efficiency higher than those of the first and second embodiments. The inlet-outlet ports 114 are the same as that of the second embodiment.

As the temperature sensor, the semiconductor pn junction diode temperature sensor is used as in the second embodiment. In this embodiment, the n-type or the P-type semiconductor substrate is used as the substrate 102, the p-type or n-type impurity area 116 is formed over the entire surface of the substrate 102 on the glass substrate 101 side to cause the same to work as the diode temperature sensor. Connection to the diode temperature sensor and the external temperature measurement system is achieved by forming the temperature sensor terminals 117 on the glass substrate 101 and the glass substrate 104 and wiring among these members. The effects are the same as those of the second embodiment, and reduction in the number of steps for manufacture as described in the next paragraph is advantageously achieved.

The shaping of the substrate 102 requires an etching process of the void ill and the flow channel 113 as in the second embodiment. However, in this embodiment, an example in which the void 111 and the flow channel 113 are both formed by anisotropic wet etching is illustrated in FIG. 12 and FIG. 13. When the surface area of the flow channel 113 is set to be smaller than the surface area of the void 111, by utilizing a feature that the cross section becomes an oblique surface due to the anisotropy of wet etching, the void 111 may be formed as a through hole when viewed from the cross section and the flow channel 113 may be formed as a partly penetrating hole when viewed from the cross section through one wet etching process. Accordingly, the manufacture is advantageously facilitated. Although the manufacture of the temperature sensor is the same as the second embodiment, a point that the impurity area is formed over the entire surface of the substrate without using the lithography or the like is different in this embodiment. Accordingly, necessity of the process of lithography or the like is advantageously eliminated.

The shaping of the glass substrate 101 and the glass substrate 104 is the same as that of the second embodiment, and a point that the temperature sensor terminals 117 are arranged respectively on the glass substrate 101 and the glass substrate 104 is different. The bonding or the joining of the glass substrate 101 and the substrate 102 and the glass substrate 104 is the same as that of the first embodiment.

In the third embodiment, the flow channel 113 is bifurcated and joined to surround the entire circumference of the void 111, and the temperature sensor is provided. However, even when one of these configurations is applied to the gas cell of the first embodiment, effects specific for the respective configurations may be obtained.

### Fourth Embodiment

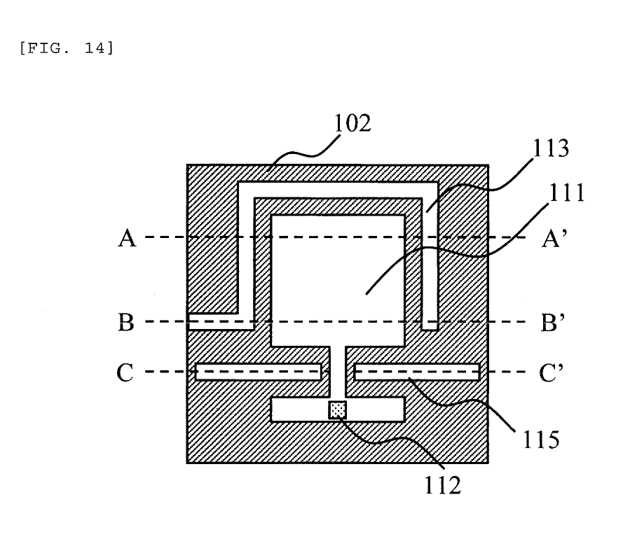

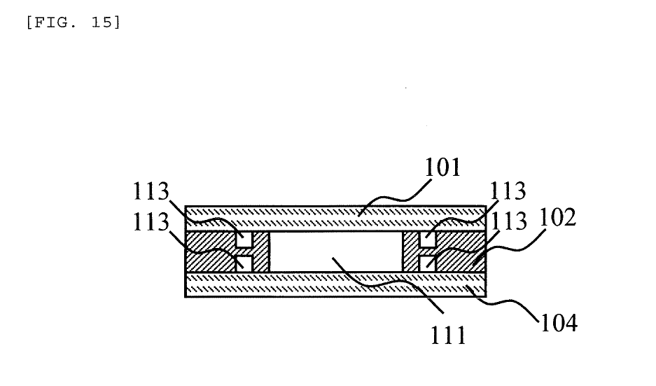

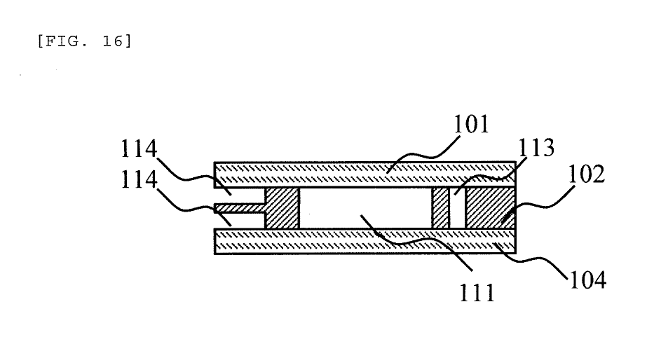

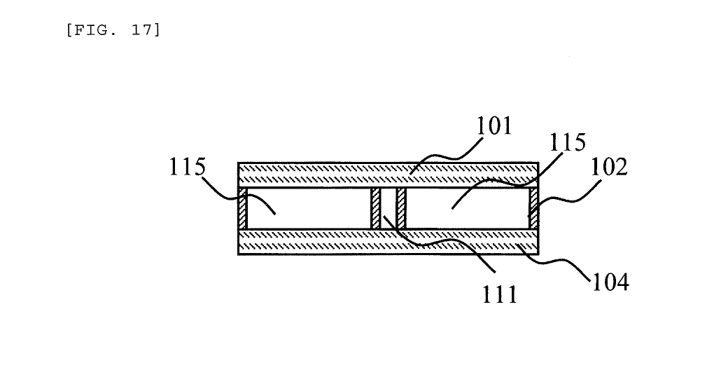

Referring to FIGS. 14 to 17, a fourth embodiment of the present invention will be described. FIG. 14 is a schematic top view of a gas cell according to the fourth embodiment. FIG. 15, FIG. 16, and FIG. 17 are schematic cross-sectional views taken along lines A-A′, B-B′, and C-C′ in FIG. 14, respectively. In the fourth embodiment, the gas cell has a configuration including three layers of the glass-substrate-glass in the same manner as the first embodiment.

The void 111 has a configuration penetrating through the substrate, and contains alkali metal gas generated from the alkali metal solid substance or liquid 112 therein. The alkali metal solid substance or liquid 112 is arranged at a portion different from a position where a laser passes through to configure the alkali metal solid substance or liquid 112 not to move to, or not to move easily to the position where the laser passes through. This is effective for suppressing the alkali metal solid substance or liquid 112 from exerting influence on transferred light when a laser beam passes through the interior of the void 111. The alkali metal solid substance or liquid 112 is the same as that of the first embodiment. Specifically, the void 111 includes a first area where the laser beam passes through the void 111 and a second area where the alkali metal solid substance or liquid, which is a source of generation of alkali metal gas, is arranged, and is realized by coupling these areas with each other with an area narrower than the respective areas.

The flow channels 113 are arranged in the periphery of a position where the laser beam of the void 111 passes through. The flow channels 113 are arranged as partly penetrating grooves on an upper part and a lower part of the substrate 102 when viewed from the cross section, and are each configured to allow heated fluid to be infused from one side and, by arranging a through hole on the opposite side, to run from the flow channel on the upper side or the lower side of the substrate to the flow channel on the lower side or the upper side, and to discharge the fluid from the original side. Accordingly, the entire length of the flow channel is elongated, so that the substrate may quickly be heated. In other words, the route of the flow channel is configured in two layers so that the route becomes longer than the case where the route of the through holes are connected by a straight line when viewed from the top.

The inlet-outlet ports 114 are arranged on the side surface of the substrate 102, and are configured to allow the heated fluid to be flowed in and out by connecting a silicone tube or the like. Also, by arranging the inlet-outlet ports 114 in the substrate 102, necessity of the shaping of the glass substrate 101 or the glass substrate 104 is advantageously eliminated.

In the fourth embodiment, a heat-insulating layer 115 is arranged between a portion of the void 111 where a laser beam passes and a portion where the alkali metal solid substance or liquid 112 is held. The heat-insulating layer 115 includes a through hole created in a substrate, and is formed of a material which resists heat transfer to the heat-insulating layer 115 interposed between the glass substrate 101 and the glass substrate 104, for example, the heat-insulating layer is a layer formed by filling a hermetically sealed space with vacuum or gas. The heat-insulating layer 115 is configured to allow only the portion where the laser beam passes to be heated and prevent the alkali metal solid substance or liquid 112 from being heated when the substrate 102 is heated by the heated fluid flowing in the flow channel 113, so that the excessive alkali metal solid substance or liquid 112 may be suppressed from concentrating to a portion at a low temperature and adhering to the portion where the laser beam passes. In order to achieve this effect, it is also effective to vary the distribution of the impurities on the substrate 102, form the impurity area only in the periphery of the portion where the laser beam passes, and vary the thermal conductivity in the substrate 102. Specifically, the heat-insulating layer 115 is preferably provided between the flow channel 113 and the second area where an alkali metal gas source is arranged. Also, the heat-insulating layer may be at least of any material as long as it resists easy heat transmission, it is preferable to be a void for the sake of convenience of the manufacturing process.

The shaping of the substrate 102 is achieved by forming patterns of the void 111 and the flow channel 113 on the substrate 102 by lithography or the like, and forming the void 111 and the flow channel 113 on the substrate 102 by etching or the like. The cross sections of the void 111 and the flow channel 113 need not to be vertical, and may be oblique, or may have a level difference. Since the void 111 forms the through hole when viewed from the cross section, and the flow channel 113 forms a partly penetrated groove when viewed from the cross section on the glass substrate 101 side and on the glass substrate 104 side of the substrate 102. Therefore, in the same manner as the second or third embodiment, there is a method of forming the flow channel 113 on the upper surface and the lower surface of the substrate 102 by forming the void 111 and the flow channel 113 on one surface of the substrate 102 and forming the flow channel 113 on the other surface of the substrate 102.

The shaping of the glass substrate 101 and the glass substrate 104 is not necessary for the inlet-outlet ports 114. The temperature sensor is the same as that of the first embodiment or the second embodiment. The bonding or the joining of the glass substrate 101 and the substrate 102 and the glass substrate 104 is the same as that of the first embodiment.

In the fourth embodiment, the shape of the void is devised, the flow channel is configured to have the two layers, the inlet-outlet ports are provided on the substrate 102, and the heat-insulating layer is provided. However, even when one of these configurations is applied to the gas cell of the first embodiment, effects specific for the respective configurations may be obtained.

### Fifth Embodiment

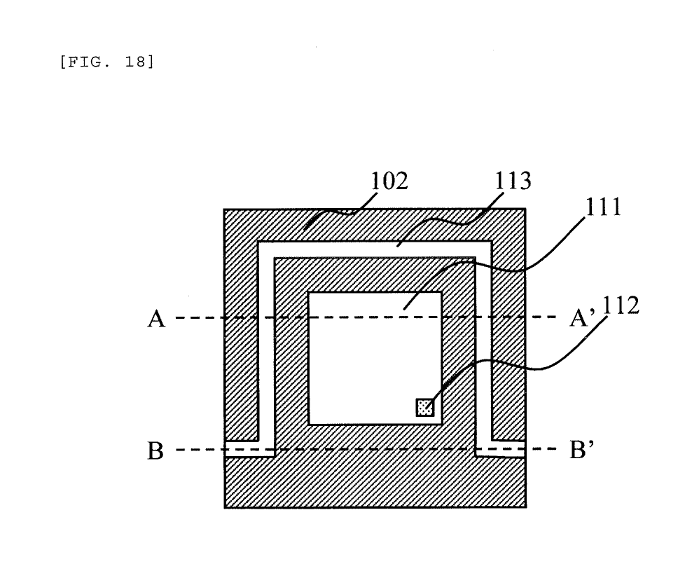

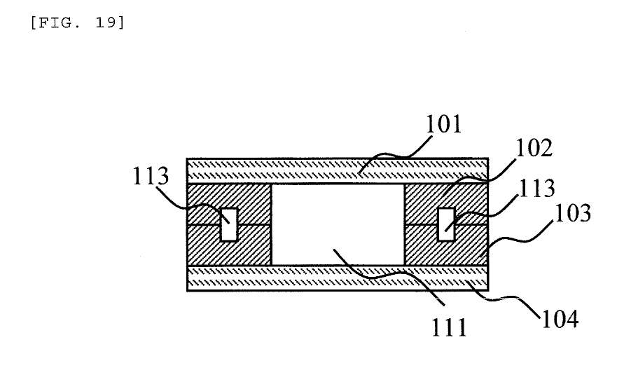

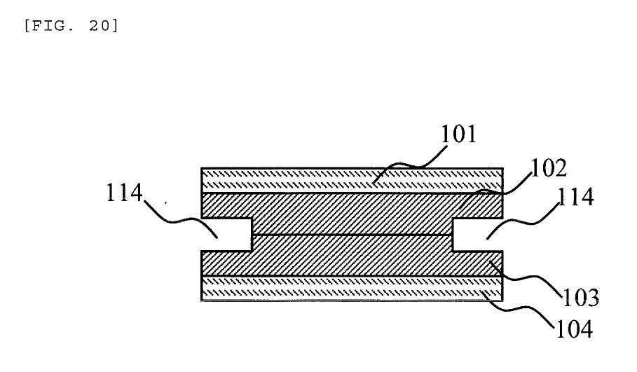

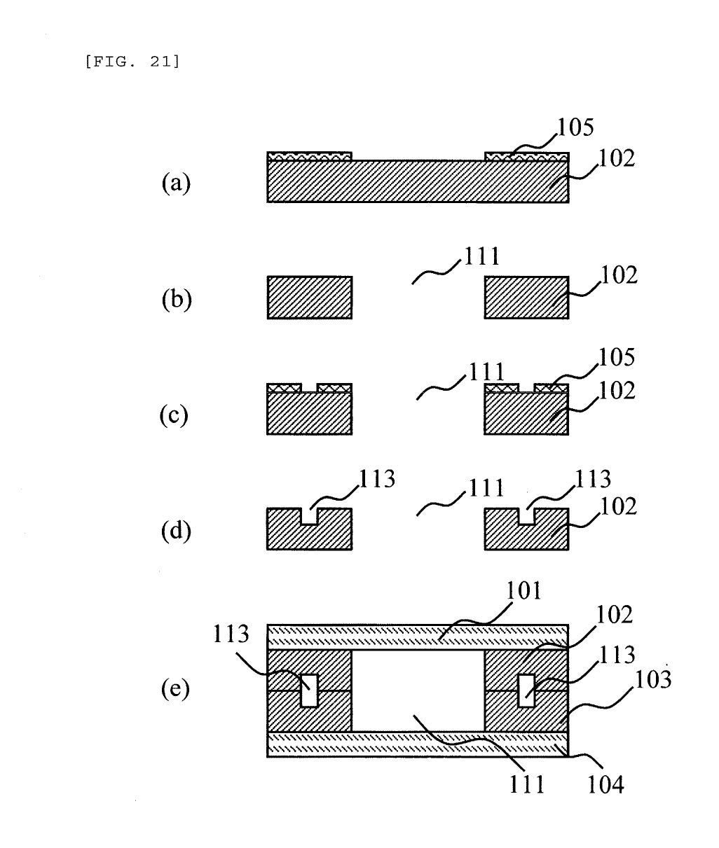

Referring to FIGS. 18 to 21, a fifth embodiment of the present invention will be described. FIG. 18 is a schematic top view of the substrate 102 in the gas cell according to the fifth embodiment. FIG. 19 and FIG. 20 are schematic cross-sectional views taken along lines A-A′ and B-B′ in FIG. 18, respectively. FIGS. 21(a), (b), (c), (d) and (e) illustrate a method of manufacturing the substrate 102 according to this embodiment by using the cross section taken along the line B-B′ in FIG. 18. In FIG. 18, the method of manufacturing the substrate 103 is the same as that of the substrate 102, the method of manufacturing the glass substrate 101 and the glass substrate 104 is omitted because it is the same as that of the first embodiment.

The gas cell according to this embodiment has a configuration composed of four layers of glass-substrate-substrate-glass, in which the glass substrate 101 is arranged on an upper surface of the substrate 102 and the substrate 103 bonded to each other, and the glass substrate 104 is arranged on a lower surface thereof. In this embodiment, two substrates are used. However, three or more substrates may be used. For the substrate 102 and the substrate 103, a material having a thermal conductivity higher than the glass substrate 101 and the glass substrate 104, for example, a semiconductor substrate such as the silicone substrate is used. The glass substrate 101 and the glass substrate 104 are the same as those of the first embodiment.

The void 111 has a configuration penetrating through the substrate 102 and the substrate 103, and contains alkali metal gas generated from the alkali metal solid substance or liquid 112 therein. The interior of the void 111 needs only to be tightly sealed in an area surrounded by the glass substrate 101 and the glass substrate 104, and also may contain nitrogen gas, noble gas, or the like or a mixed atmosphere thereof instead of the alkali metal gas. In FIG. 14, the shape of the void 111 is a rectangular shape. However, an area surrounded by other polygonal shapes or a curved line may be used. In this embodiment, a laser beam is radiated from the upper glass substrate 101 toward the lower glass substrate 104, and the laser beam passes through the void 111, whereby the magnetic field is measured. The alkali metal solid substance or liquid 112 is the same as that of the first embodiment.

The flow channel 113 is arranged so as to surround the periphery of the rectangular void 111 with straight lines over three sides thereof. The flow channel 113 is configured not to penetrate through the substrate 102 and the substrate 103 when viewed from the cross section, and the flow channel 113 is formed by putting the partly penetrated grooves formed on the substrate 102 and the substrate 103 together so as to face each other. Accordingly, the heated fluid flowing in the flow channel 113 does not come into contact with the glass substrate 101 and the glass substrate 104, and is in contact with the respective glass substrates via parts of the substrates 102 and 103 with the both glass substrates, so that heat of the fluid may be transferred only to the substrate efficiently.

The inlet-outlet ports 114 are arranged on the side surfaces of the substrate 102 and the substrate 103, and configured to allow the heated fluid to be infused from the outside into one of the inlet-outlet ports, and discharge the fluid from the other inlet-outlet port.

Subsequently, an example of a procedure of manufacturing the gas cell for implementing the fifth embodiment will be described (FIG. 21). In this embodiment, the silicon substrate having a thermal conductivity higher than that of the glass is used as the substrate 102 and the substrate 103 as an example. The substrate may be subjected to processing such as impurity doping in order to enhance the thermal conductivity. A pattern of the void 111 is formed on the mask materials 105 formed on the substrate 102 and the substrate 103 by lithography or the like, and the void ill is formed on the substrate 102 and the substrate 103 by dry etching or the like. The cross section of the void 111 needs not to be vertical, and may be oblique, or may have a level difference. Subsequently, new mask materials 105 are formed on the substrate 102 and the substrate 103, a pattern of the flow channel 113 is formed on the mask materials 105 formed on the substrate 102 and the substrate 103 by lithography or the like, and the flow channel 113 is formed on the substrate 102 and the substrate 103 by dry etching or the like. The cross section of the flow channel 113 needs not to be vertical, and may be oblique, or may have a level difference.

The void 111 is formed by creating a through hole when viewed from the cross section, and the flow channel 113 is formed by creating a partly penetrated groove when viewed from the cross section. Therefore, there is a method of drawing the patterns of the void 111 and the flow channel 113 on the upper surface of the substrate 102, drawing the pattern of the void 111 on the lower surface, and wet etching or the like from the both surfaces of the substrate simultaneously in addition to the above-described example of the procedure of manufacture. Alternatively, the void 111 and the flow channel 113 may be formed directly by processing the substrate 102 with a laser or a drill. The glass substrate 101 and the glass substrate 104 are the same as those of the first embodiment.

The glass substrate 101, the substrate 102, the substrate 103, and the glass substrate 104 are bonded or joined and sealed in a state of containing the alkali metal solid substance or liquid 112 in the void 111. For example, there is a method of directly joining the silicone substrates with each other and joining the silicone substrate and borosilicate glass by anode joining. In addition, a method of setting an atmosphere for bonding or joining the glass substrate 101 or the glass substrate 104 with inactive gas or noble gas such as nitrogen and encapsulating these gases in the void 111 at the same time is also applicable. Between the substrate and the substrate, and between the glass substrate and the substrate are only required to be kept in hermeticity and an adhesive agent or the like may be used.

In the fifth embodiment, a four-layer structure is employed so as not to come into contact with the both glass substrates, and the inlet-outlet ports are provided on the substrates 102 and 103. However, even when one of these configurations is applied to the gas cell of the first embodiment, effects specific for the respective configurations may be obtained.

### Sixth Embodiment

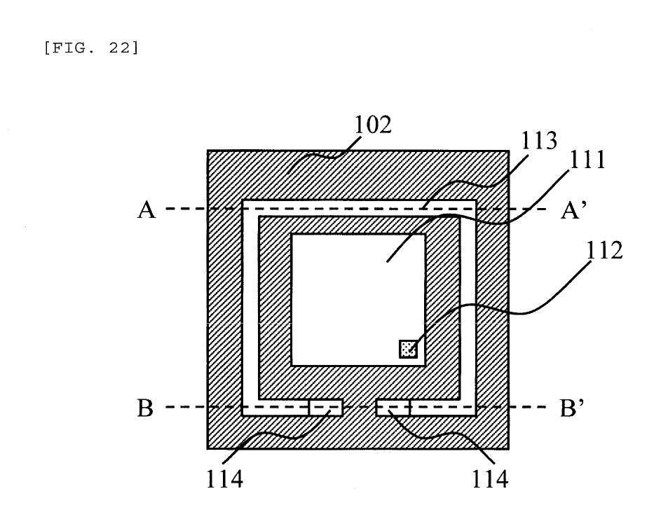

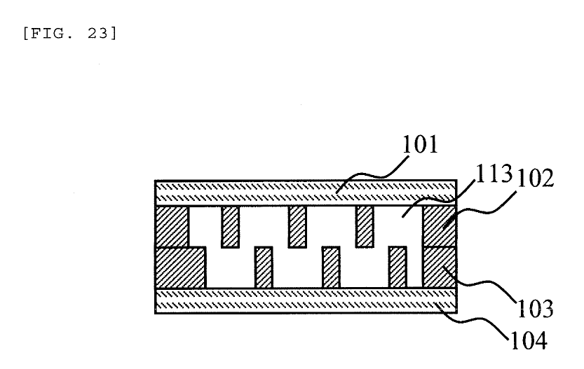

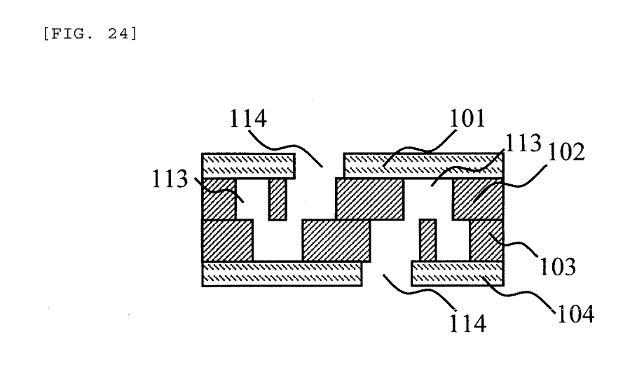

Referring to FIGS. 22 to 24, a sixth embodiment of the present invention will be described. FIG. 22 is a schematic top view of a gas cell according to the sixth embodiment. FIG. 23 and FIG. 24 are schematic cross-sectional views taken along lines A-A′ and B-B′ in FIG. 22, respectively. In the sixth embodiment, the gas cell has a configuration including four layers of the glass-substrate-substrate-glass in the same manner as that of the fifth embodiment. The void 111 is the same as that of the fifth embodiment. The alkali metal solid substance or liquid 112 is the same as that of the first embodiment.

The flow channel 113 is arranged so as to surround the periphery of the void ill in parallel to the substrate 102 and the substrate 103. The flow channel 113 is formed by arranging the through holes so as to pass through the substrate 102 and the substrate 103 alternately when viewed from the cross section. This configuration has an effect of increasing the surface area facing the void than the configuration of elongating the entire length of the route of the flow channel by forming the flow channel so as to snake through and connecting the straight lines parallel to the four sides of the substrate 102 when viewed from the top, and allows the flow channel 113 and the void 111 to be arranged closer to each other in comparison with the second embodiment by the zigzag arrangement so as to snake through in the vertical direction of the substrate and, in addition, allows heat to be transferred to the alkali metal gas in the void efficiently.

The inlet-outlet ports 114 are the same as those of the first embodiment. In FIG. 19, the inlet-outlet ports 114 are arranged one each in the glass substrate 101 and the glass substrate 104. However, two of the inlet-outlet ports 114 may be collectively provided on one of the glass substrates.

The shaping of the substrate 102 and the substrate 103 is the same as that of the first embodiment, and the substrate 102 and the substrate 103 are used by being bonded or joined after the formation of the void 111 and the flow channel 113. The shaping of the glass substrate 101 and the glass substrate 104 are the same as those of the first embodiment or the second embodiment. The bonding or the joining between the glass substrate 101 and the substrate 102, and between the substrate 103 and the glass substrate 104 is the same as that of the first embodiment.

In the sixth embodiment, the four-layer structure is employed to cause the flow channel to snake through. However, even when one of these configurations is applied to the gas cell of the first embodiment, specific effects may be obtained.

### Seventh Embodiment

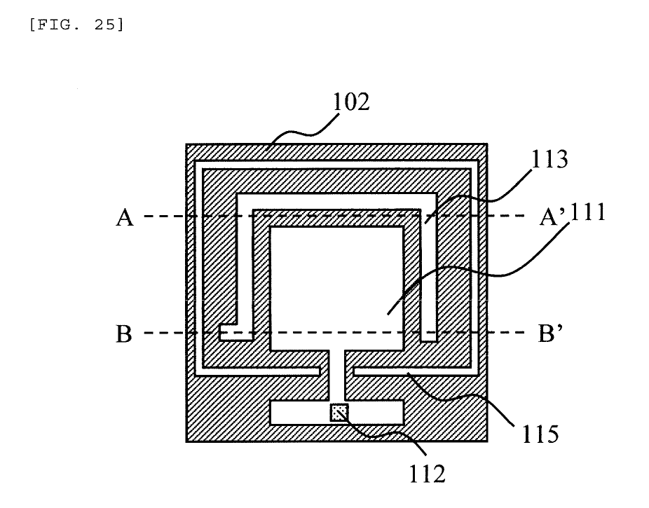

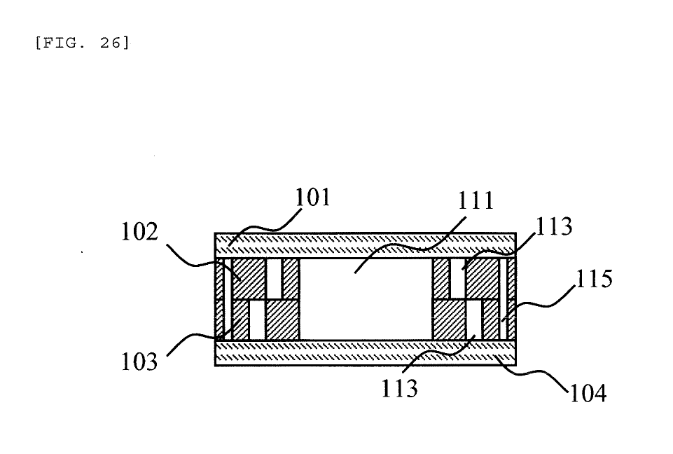

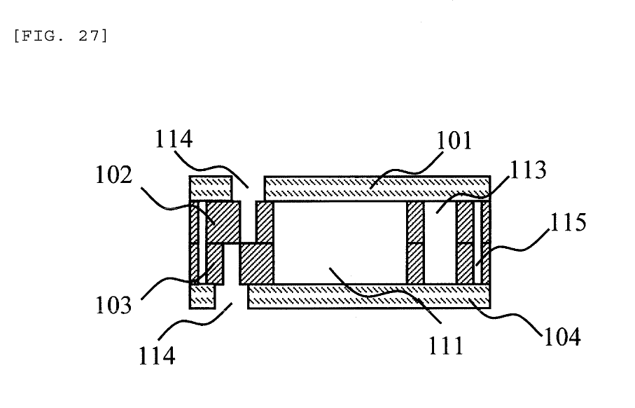

Referring to FIG. 25 to FIG. 27, a seventh embodiment of the present invention will be described. FIG. 25 is a schematic top view of the gas cell according to the seventh embodiment. FIG. 26 and FIG. 27 are schematic cross-sectional views taken along lines A-A′ and B-B′ in FIG. 25, respectively. In the seventh embodiment, the gas cell has a configuration including four layers of the glass-substrate-substrate-glass in the same manner as in the fifth embodiment. The void 111 is the same as that of the fourth embodiment. The alkali metal solid substance or liquid 112 is the same as that of the first embodiment.

Although the flow channels 113 are arranged in the same manner as those of the fourth embodiment, the flow channels 113 are formed on the substrate 102 and the substrate 103, and the respective flow channels 113 are arranged with shift so as not to be connected at portions other than ends opposite to the inlet-outlet ports 114, respectively. The flow channels 113 in the substrate 102 and the substrate 103 are connected at the ends opposite to the inlet-outlet ports 114. In other words, the flow channels 113 have the two-layer structure, and hence the same effect as of the fourth embodiment is achieved.

In the sixth embodiment, the heat-insulating layer 115 is provided in the same manner as that of the fourth embodiment. However, in the sixth embodiment, the heat-insulating layer 115 is provided not only between the flow channel 113 and the second area where the alkali metal gas source is arranged, but also arranged so as to surround the periphery of the flow channel. This configuration reduces leakage of heat of the fluid to the outside or the influence of outside air on the outside in addition to the effect of the fourth embodiment, so that the alkali metal gas in the void 111 may be warmed up efficiently.

The inlet-outlet ports 114 are the same as those of the first embodiment. The shaping of the substrate 102 and the substrate 103 is the same as that of the sixth embodiment. The shaping of the glass substrate 101 and the glass substrate 104 is the same as that of the first embodiment. The bonding or the joining between the glass substrate 101 and the substrate 102, and between the substrate 103 and the glass substrate 104 is the same as that of the first embodiment.

In the seventh embodiment, the shape of the void is devised, the four-layer structure is employed and the flow channel is configured to have the two layers, and the heat-insulating layer is provided. However, even when one of these configurations is applied to the gas cell of the first embodiment, effects specific for the respective configurations may be obtained.

### Eighth Embodiment

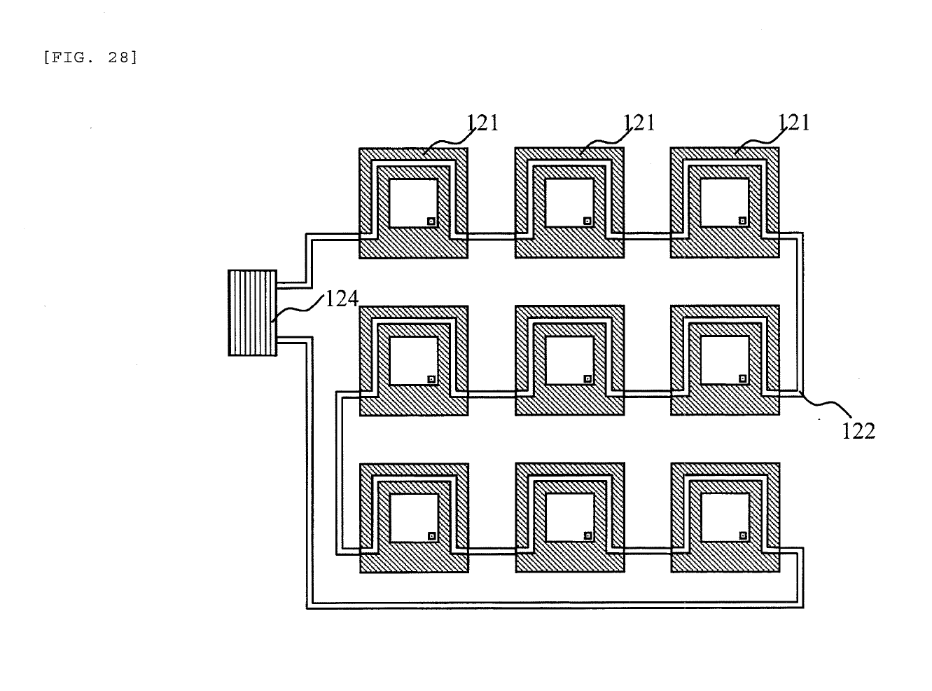

Referring to FIG. 28, an eighth embodiment of the present invention will be described. FIG. 28 illustrates a system configured to circulate heated fluid in series by arranging a plurality of gas cells 121 having configuration of the first to seventh embodiments in an array pattern, connecting the same in sequence by hollow tubing 122 such as a silicon tube, and connecting the gas cell array to an external heater configured to warm up the fluid and a pump 124 configured to cause the fluid to flow into the hollow tubing.

In this embodiment, the gas cell 121 illustrates the gas cell 121 according to the fifth embodiment. However, the gas cell 121 of other embodiments may be used and a combination of a plurality of types of the gas cells 121 may be used. In FIG. 25, nine gas cells are arranged in an array pattern, the number of the gas cells to be arranged is not limited.

The hollow tubing 122 is hollow and is formed of a non-magnetic material, for example, the silicone tube or the like. The hollow tubing 122 is formed to have a shape which may come into tight contact with the inlet-outlet ports 114 arranged in the gas cell 121, and is fixed with an adhesive agent or the like. The external heater and the pump 124 are arranged out of a magnetic field so as to avoid the influence exerted upon the magnetic field that a magnetometer measures. In the eighth embodiment, the external heater and the pump 124 are each arranged at one position. However, the external heaters and the pumps may be inserted at a plurality of positions as needed.

In the system configuration of the eighth embodiment, the tubing 122 is connected to outputs of the external heater and the pump 124, and is connected to one of the inlet-outlet ports 114 of the gas cell 121. The tubing 122 is connected from the other one of the inlet-outlet ports 114 of the gas cell 121 to one of the inlet-outlet ports 114 of the next gas cell 121. Such a connection is repeated by the number of the required gas cells, and the tubing 122 is connected from the inlet-outlet ports 114 of the final gas cell to inputs of the external heater and the pump 124 again.

### Ninth Embodiment

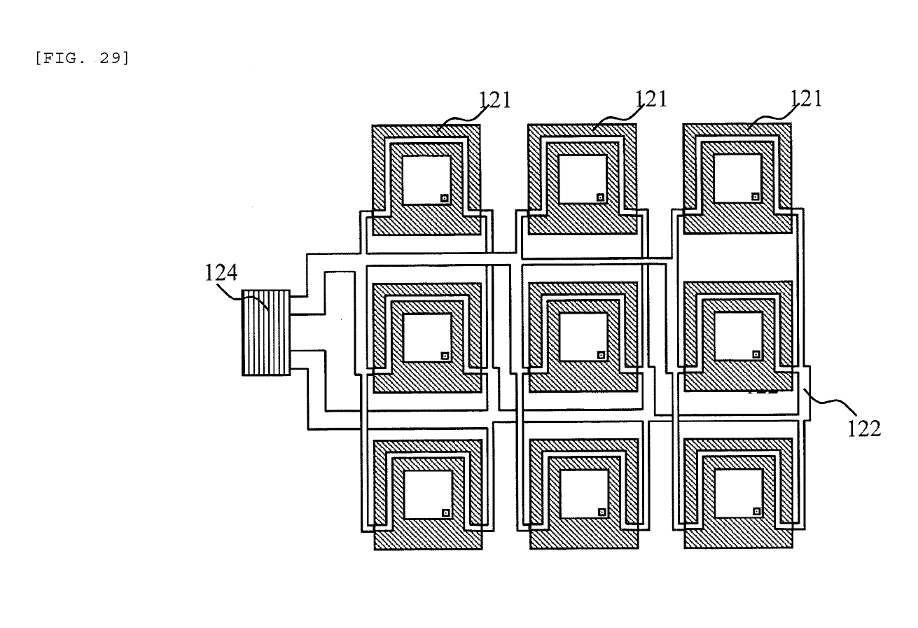

Referring to FIG. 29, a ninth embodiment of the present invention will be described. FIG. 29 illustrates a system configured to circulate heated fluid in parallel by arranging the plurality of gas cells 121 having configurations of the first to seventh embodiments in an array pattern, bifurcating the hollow tubing 122 such as the silicone tube and connecting the same to the respective gas cells 121, and connecting the gas cell array to the external heater configured to warm up the fluid and the pump 124 configured to cause the fluid to flow into the hollow tubing. The gas cells 121 are the same as those of the eighth embodiment.

The tubing 122 is the same as that of the eighth embodiment, is provided with a bifurcation at a midsection thereof, and is connected to the gas cells 121 in parallel. Since the flow rate in the tubing is reduced as it goes away from the external heater and the pump 124, the cross-sectional area of the tubing 122 includes a plurality of cross-sectional areas such as being reduced as it goes away from the external heater and the pump. Since the fluid heated by the heater flows directly into the respective gas cells 121 in comparison with the eighth embodiment in which the gas cells 121 are connected in series, the time required until the respective gas cells are heated is advantageously reduced. The external heater and the pump 124 are the same as those of the eighth embodiment.

In the system configuration of the ninth embodiment, the tubing 122 is connected to the outputs of the external heater and the pump 124, the bifurcation is provided in the midsection of the tubing 122, and the bifurcated tubing 122 is connected to one of the inlet-outlet ports 114 of the gas cells 121. The other inlet-outlet ports 114 of the gas cells 121 are collected to the tubing 122 in the reverse order from that described above, and are connected to the inputs of the external heater and the pump 124.

### Tenth Embodiment

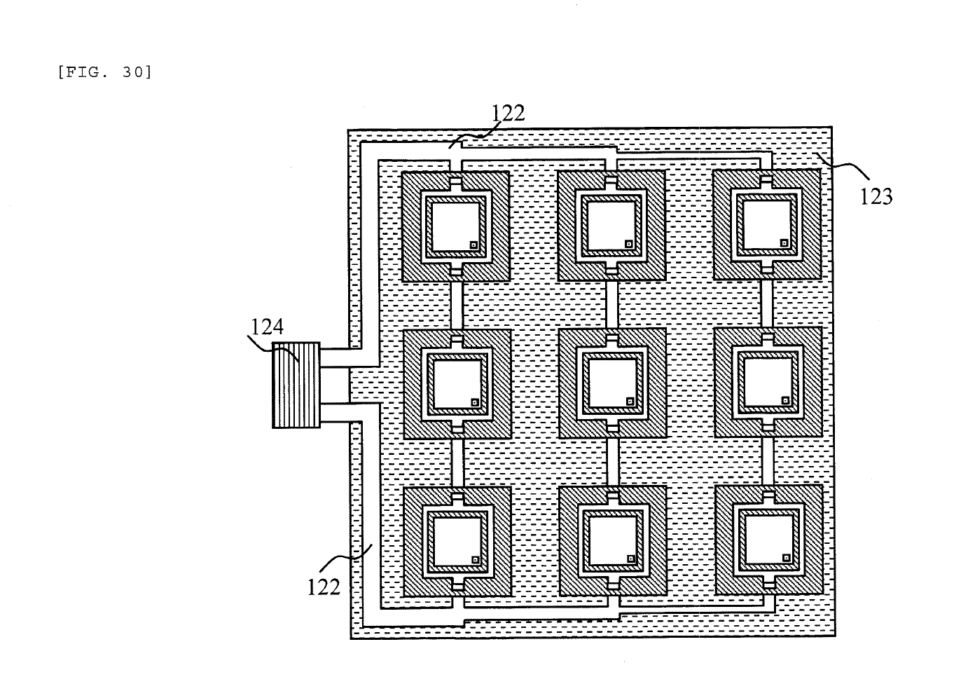

Referring to FIG. 30, a tenth embodiment of the present invention will be described. In FIG. 30, the plurality of gas cells 121 having configurations of the first to seventh embodiments are arranged on a substrate with tubing 123 in an array pattern, and the inlet-outlet ports 114 of the respective gas cells 121 and the tubing on the substrate with tubing 123 are connected. On the substrate with tubing 123, the gas cell array is connected to the external heater configured to warm up the fluid and the pump 124 configured to allow the fluid to flow into the hollow tubing by the tubing 122. The gas cells 121 are the same as those of the eighth embodiment. The inlet-outlet ports 114 of the gas cells 121 are preferably arranged on the lower surface of the gas cells. The tubing 122 is the same as that of the eighth embodiment.

The substrate with tubing 123 includes a flow channel configured to allow heated fluid to flow into the interior of the substrate and is composed of, for example, a plastic mold or the like. The substrate with tubing 123 needs to be transparent with respect to the laser beam at least at a portion where the laser beam passes. The substrate with tubing 123 and the gas cells 121 are connected with an adhesive agent or the like, and, simultaneously, are connected to the inlet-outlet ports 114 on the lower surfaces of the gas cells and the tubing portion of the substrate with tubing 123 or are connected to the inlet-outlet ports 114 of the gas cells and a tubing portion of the substrate with tubing 123 by using the tubing 122. In the tenth embodiment, by connecting in a combination of series and parallel, complication of the tubing may be resolved. Also, by using the substrate with tubing 123, the gas cells 121 arranged in the array pattern and the tubing 122 are effectively fixed. These effects are respectively independent, and hence connection of the tubing in combination of series and parallel and using the substrate with tubing may be implemented separately. The external heater and the pump 124 are the same as that of the eighth embodiment.

In a system configuration of the tenth embodiment, the outputs of the external heater and the pump 124, and the substrate with tubing 123 are connected with the tubing 122, and heated fluid is flowed into the flow channel of the gas cell 121 arranged on the substrate with tubing 123, and the gas cells 121 are heated. The gas cells 121 are arranged on the substrate with tubing 123 in combination of series and parallel.

### REFERENCE SIGNS LIST

101 glass substrate
102 substrate
103 substrate
104 glass substrate
105 mask material
111 void
112 alkali metal solid substance or liquid
113 flow channel (through hole)
114 inlet-outlet port
115 heat-insulating layer
116 impurity area
117 temperature sensor terminal
121 gas cell
122 tubing
123 substrate with tubing
124 external heater and pump

1. A magnetic measurement apparatus comprising:
a laminated substrate including first and second glass substrates and a third substrate having a thermal conductivity higher than glass arranged between the first glass substrate and the second glass substrate;
a void formed in the third substrate and filled with alkali metal gas; and
a through hole formed in the third substrate so as to penetrate through two openings formed in the laminated substrate.

2. The magnetic measurement apparatus according to claim 1, characterized in that the through hole is a through hole that allows fluid for adjusting the temperature of the alkali metal gas to flow.

3. The magnetic measurement apparatus according to claim 1, characterized in that the void has a rectangular shape when viewed from the top and the through hole surrounds three sides of the rectangular shape when viewed from the top.

4. The magnetic measurement apparatus according to claim 1, characterized in that the through hole is bifurcated at a midsection, the bifurcated through holes are coupled at a midsection, and surround the void when viewed from the top.

5. The magnetic measurement apparatus according to claim 1, characterized in that the through hole is formed so as to sneak through the third substrate.

6. The magnetic measurement apparatus according to claim 1, characterized in that the void has a rectangular shape when viewed from the top and the through hole surrounds the three sides of the rectangular shape when viewed from the top, the through hole snakes through so as to increase the surface area on the side facing the void in a case where the route of the through hole is connected with a straight line when viewed from the top, or the through hole includes two layers so as to increase the length of the route than the case where the route of the through hole is connected with the straight line when viewed from the top.

7. The magnetic measurement apparatus according to claim 1, characterized in that the through hole is in contact with the one of the first and second glass substrates via part of the third substrate, or is in contact with the both glass substrates via the part of the third substrate.

8. The magnetic measurement apparatus according to claim 1, further comprising a thermal insulating layer on the third substrate.

9. The magnetic measurement apparatus according to claim 1, characterized in that the void includes a first area where a laser beam passes and a second area in which a solid substance or liquid as the alkali metal gas generating source is arranged, the first area and the second area being connected each other, and the through hole is arranged in a route facing the first area, and
further includes a hermetically sealed second void between the through hole and the second area.

10. The magnetic measurement apparatus according to claim 1, characterized in that the third substrate is formed of a semiconductor, and the semiconductor is formed with a pn junction diode.

11. The magnetic measurement apparatus according to claim 1, wherein both of the two openings are formed on any one of the first glass substrate, the second glass substrate, and the third substrate.

12. The magnetic measurement apparatus according to claim 1, characterized in that both of the two openings are formed on any one of the first glass substrate and the second glass substrate, and on the same surface of the corresponding glass substrate.

13. The magnetic measurement apparatus according to claim 1, characterized in that the third substrate includes a plurality of substrates.

14. The magnetic measurement apparatus according to claim 1, characterized in that each of the two openings has a diameter larger than a diameter of the through hole.

15. The magnetic measurement apparatus according to claim 1, characterized in that the third substrate is formed of a semiconductor.

16. The magnetic measurement apparatus according to claim 1, characterized in that the third substrate is formed of silicon.

17. The magnetic measurement apparatus according to claim 1, characterized in that a plurality of the magnetic measurement apparatuses according to claim 1 are arranged two dimensionally, and the through holes of the respective magnetic field measurement apparatuses are connected in series, in parallel, or in combination of the series and the parallel with hollow tubing.

18. The magnetic measurement apparatus according to claim 17, characterized in that the hollow tubing has a plurality of different cross-sectional areas.

19. The magnetic measurement apparatus according to claim 18, further comprising a heater configured to warm up fluid to be flowed to the through hole, and a pump configured to cause the fluid to flow into the hollow tubing, and the cross-sectional area of the hollow tubing is reduced as it goes away from the pump.
